(19) United States
(12) Patent Application Publication
(10) Pub. No.: US 2014/0076380 A1
(43) Pub. Date: Mar. 20, 2014

(54) Concentrating Solar Energy Collector

(71) Applicant: COGENRA SOLAR, INC., Mountain View, CA (US)

(72) Inventors: Jason C. Kalus, San Francisco, CA (US); Adam T. Clavelle, San Francisco, CA (US); Nathan P. Beckett, Oakland, CA (US); Ratson Morad, Palo Alto, CA (US); Gilad Almogy, Palo Alto, CA (US)

(73) Assignee: Cogenra Solar, Inc., Mountain View, CA (US)

(21) Appl. No.: 13/763,429

(22) Filed: Feb. 8, 2013

Related U.S. Application Data
(63) Continuation-in-part of application No. 13/651,246, filed on Oct. 12, 2012.
Application No. 13/651,246 is a continuation-in-part of application No. 13/619,952, filed on Sep. 14, 2012.
Application No. 13/619,952 is a continuation-in-part of application No. 13/619,881, filed on Sep. 14, 2012.
Application No. 13/619,881 is a continuation-in-part of application No. 13/633,307, filed on Oct. 2, 2012.

(51) Int. Cl. H01L 31/052

(52) U.S. Cl. CPC H01L 31/0525
USPC 136/246

(57) ABSTRACT

Systems, methods, and apparatus by which solar energy may be collected to provide heat, electricity, or a combination of heat and electricity are disclosed herein.

### CROSS-REFERENCE TO RELATED APPLICATIONS

This application is a continuation-in-part of each of the following: U.S. patent application Ser. No. 13/651,246 titled “Concentrating Solar Energy Collector” filed Oct. 12, 2012; U.S. patent application Ser. No. 13/619,952 titled “Concentrating Solar Energy Collector” filed Sep. 14, 2012; U.S. patent application Ser. No. 13/619,881 titled “Concentrating Solar Energy Collector” filed Sep. 14, 2012; and U.S. patent application Ser. No. 13/633,307 titled “Concentrating Solar Energy Collector” filed Oct. 2, 2012; each of which is incorporated herein by reference in its entirety.

### BACKGROUND

1. Field of the Invention

The invention relates generally to a solar energy collecting apparatus to provide electric power, heat, or electric power and heat, and more particularly to a parabolic trough solar collector for use in concentrating photovoltaic systems.

2. Description of the Related Art

Alternate sources of energy are needed to satisfy ever increasing world-wide energy demands. Solar energy resources are sufficient in many geographical regions to satisfy such demands, in part, by photoelectric conversion of solar flux into electric power and thermal conversion of solar flux into useful heat. In concentrating photovoltaic systems, optical elements are used to focus sunlight onto one or more solar cells for photoelectric conversion or into a thermal mass for heat collection.

In an exemplar concentrating photoelectric system, a system of lenses and/or reflectors constructed from less expensive materials can be used to focus sunlight on smaller and comparatively more expensive solar cells. The reflector may focus sunlight onto a surface in a linear pattern. By placing a strip of solar cells or a linear array of solar cells in the focal plane of such a reflector, the focused sunlight can be absorbed and converted directly into electricity by the cell or the array of cells. Concentration of sunlight by optical means can reduce the required surface area of photovoltaic material needed per watt of electricity generated, while enhancing solar-energy conversion efficiency.

### SUMMARY

Systems, methods, and apparatus by which solar energy may be collected to provide electricity, heat, or a combination of electricity and heat are disclosed herein.

In one aspect, a solar energy collector comprises a linearly extending receiver comprising solar cells and at least a first and a second trough reflector arranged end-to-end with their linear foci oriented parallel to a long axis of the receiver and located at or approximately at the receiver. The trough reflectors are fixed in position with respect to each other and with respect to the receiver. A linearly extending support structure accommodates rotation of the trough reflectors and the receiver about a rotation axis parallel to the long axis of the receiver. Adjacent ends of the trough reflectors are located at different heights from the rotation axis. In use, the reflectors and the receiver are rotated about the rotation axis to track the sun such that solar radiation incident on the reflectors is concentrated onto the receiver.

The vertically offset adjacent ends of the trough reflectors may overlap. In some variations, for each pair of adjacent trough reflector ends the upper trough reflector is located further from the equator than is the lower trough reflector.

Each trough reflector may comprise a plurality of reflective slats oriented with their long axes parallel to the long axis of the receiver and arranged side-by-side in a direction transverse to the long axis of the receiver on a flexible sheet of material to which they are attached. The reflective slats may be attached to the flexible sheets with an adhesive that covers the entire bottom surface of each reflective slat. The adhesive may advantageously seal the edges and bottom surfaces of the reflective slats. The reflective slats may be, for example, flat or substantially flat. The flexible sheet may be or include, for example, a flexible metal sheet.

In some variations, each flexible sheet is flexed to match a curvature of an underlying portion of the support structure to which it is attached, thereby orienting its reflective slats to concentrate solar radiation onto the receiver during operation of the solar energy collector. Each flexible sheet with its attached reflective slats may have a flat free state when not secured to the support structure and exert a restoring force to return to its flat state when flexed to match the curvature of the underlying support structure. The support structure may comprise a plurality of transverse reflector supports extending away from the rotation axis and providing the curvature to which the flexible sheets are matched.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIGS. 1A-1C show front (FIG. 1A), rear (FIG. 1B) and side (FIG. 1C) views of an example solar energy collector.

FIG. 2A shows, in an exploded view, details of a transverse reflector support mounted to a rotation shaft and mounting locations for reflectors including reflectors pre-final assembly as they are assembled to a mounted position on the transverse reflector support.

FIG. 2B shows, in a perspective view, a partial end view of the underside of a reflector.

FIG. 2C shows a cross-sectional schematic view of an end-to-end arrangement of reflectors attached to a shared transverse reflector support.

FIGS. 3A-3C show front side views of a reflector.

FIGS. 4A-4B schematically illustrates two example end-to-end reflector arrangements at gaps between adjacent reflectors.

FIG. 4C illustrates an example end-to-end reflector arrangement with the adjacent ends of two reflectors vertically offset and overlapped.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the description. The detailed description illustrates by way of example, not by way of limitation, the principles of the invention. This description will clearly enable one skilled in the art to make and use the invention, and describes several embodiments, adaptations, variations, alternatives and uses of the invention, including what is presently believed to be the best mode of carrying out the invention.

As used in this specification and the appended claims, the singular forms “a,” “an,” and “the” include plural referents unless the context clearly indicates otherwise. Also, the term “parallel” is intended to mean “parallel or substantially parallel” and to encompass minor deviations from parallel geometries rather than to require that any parallel arrangements described herein be exactly parallel. Similarly, the term “perpendicular” is intended to mean “perpendicular or substantially perpendicular” and to encompass minor deviations from perpendicular geometries rather than to require that any perpendicular arrangements described herein be exactly perpendicular.

This specification discloses apparatus, systems, and methods by which solar energy may be collected to provide electricity, heat, or a combination of electricity and heat.

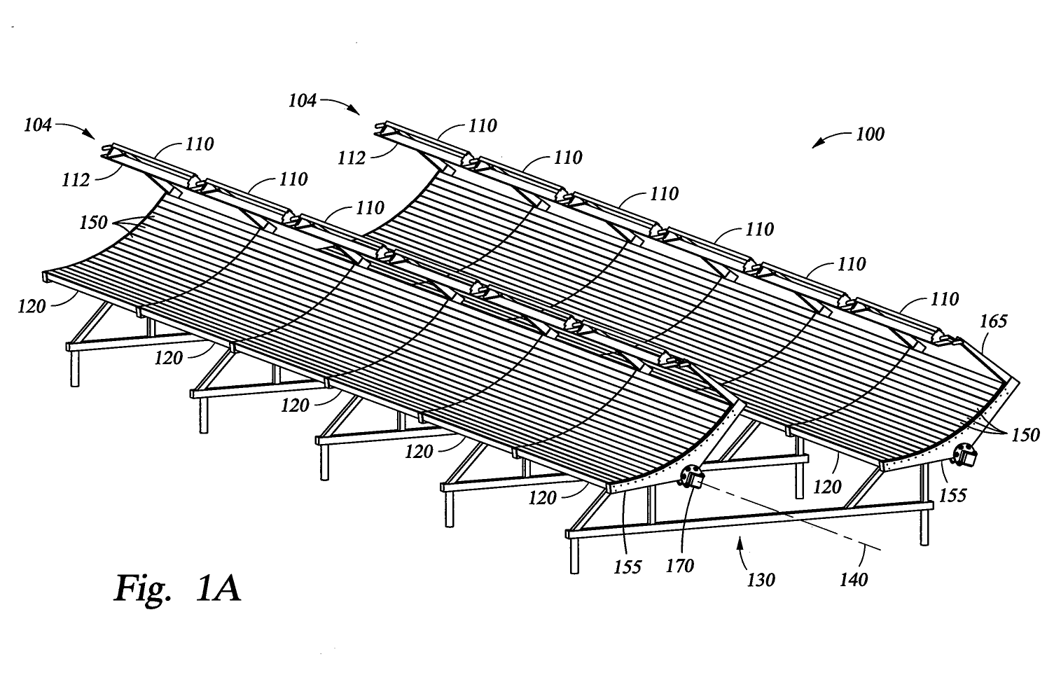

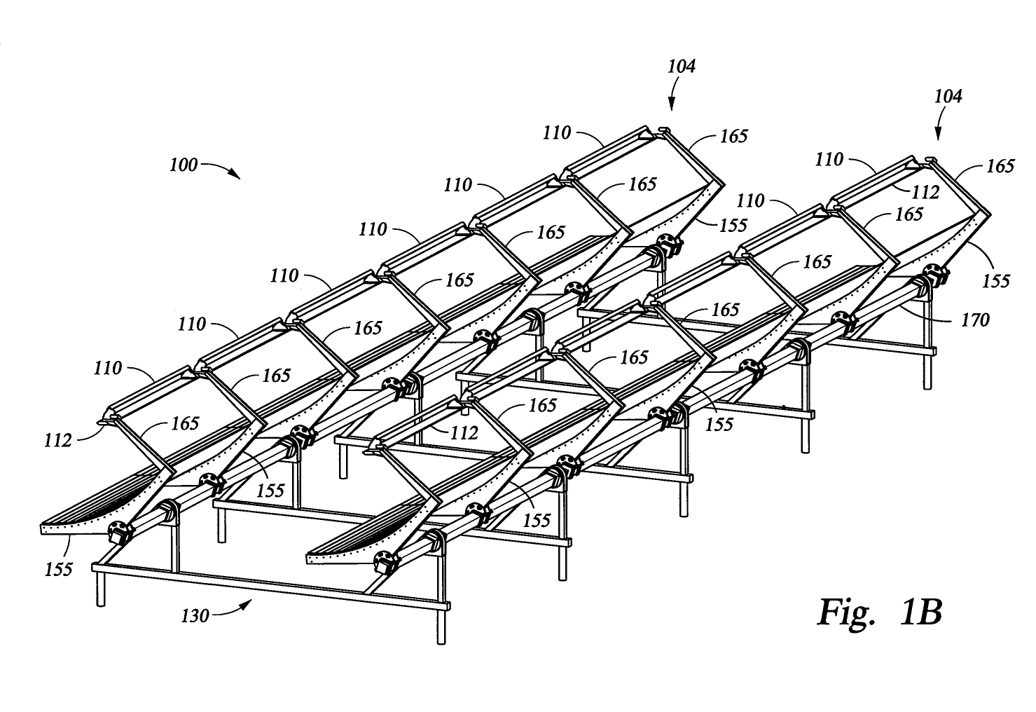

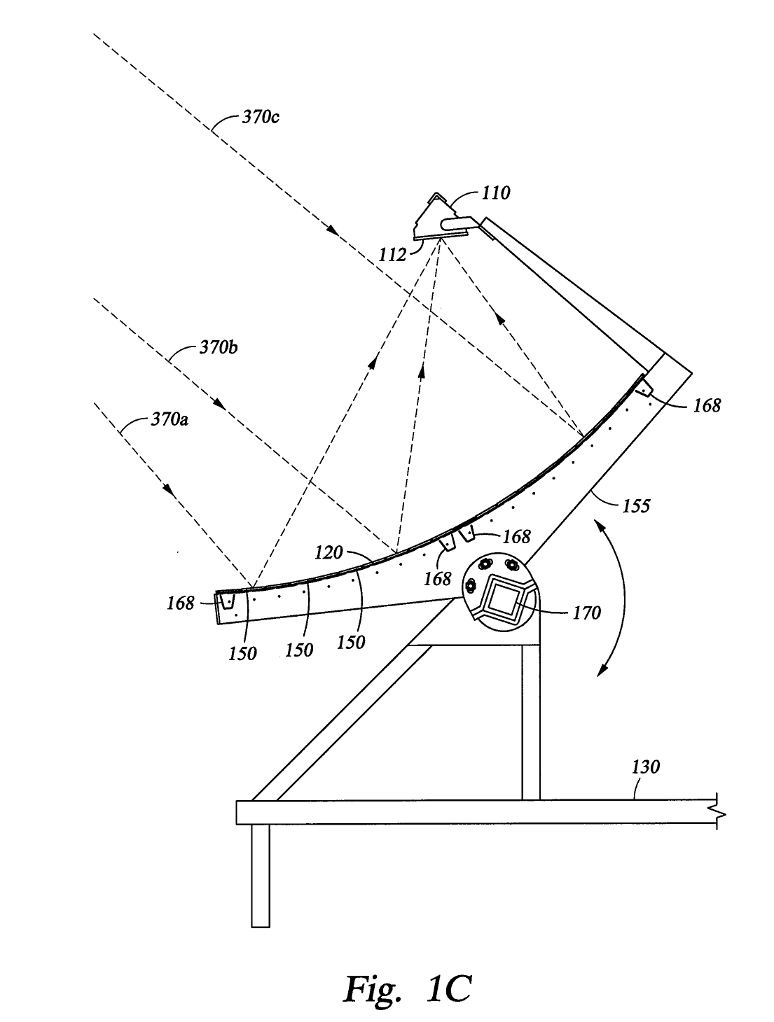

Referring now to FIGS. 1A-1C, an example solar energy collector 100 comprises one or more rows 104 of solar energy reflectors and receivers with the rows arranged parallel to each other and side-by-side. Each such row comprises one or more linearly extending reflectors 120 arranged in line so that their linear foci are collinear, and one or more linearly extending receivers 110 arranged in line and fixed in position with respect to the reflectors 120, with each receiver 110 comprising a surface 112 located at or approximately at the linear focus of a corresponding reflector 120. A support structure 130 pivotably supports the reflectors 120 and the receivers 110 to accommodate rotation of the reflectors 120 and the receivers 110 about a rotation axis 140 parallel to the linear focus of the reflectors. In use, as illustrated in FIG. 1C, the reflectors 120 and receivers 110 are rotated about rotation axes 140 (best shown in FIG. 1A) on rotation shaft 170 to track the sun such that solar radiation (light rays 370a, 370b and 370c) on reflectors 120 is concentrated onto and across receivers 110, (i.e., such that the plane containing the optical axes of reflectors 120 is directed at the sun).

In other variations, a solar energy collector otherwise substantially identical to that of FIGS. 1A-1C may comprise only a single row 104 of reflectors 120 and receivers 110, with support structure 130 modified accordingly.

As is apparent from FIGS. 1A and 1B solar energy collector 100 may be viewed as having a modular structure with reflectors 120 and receivers 110 having approximately the same length, and each pairing of a reflector 120 with a receiver 110 being an individual module. Rows 104 of solar energy collector 100 may thus be scaled in size by adding or removing such interconnected modules at the ends of solar energy collector 100, with the configuration and dimensions of support structure 130 adjusted accordingly.

Although each reflective surface of the reflector 120 has a parabolic or approximately parabolic profile in the illustrated example, this is not required. In other variations, reflectors 120 may have reflective surfaces having any curvature suitable for concentrating solar radiation onto a receiver.

In the example of FIGS. 1A-1C, each reflector 120 comprises a plurality of linear reflective elements 150 (e.g., mirrors) linearly extended and oriented parallel to the linear focus of the reflector 120 and fixed in position with respect to each other and with respect to the corresponding receiver 110. As shown, linear reflective elements 150 each have a length equal or approximately equal to that of reflector 120 and are arranged side-by-side to form the reflector 120. In other variations, however, some or all of linear reflective elements 150 may be shorter than the length of reflector 120, in which case two or more linearly reflective elements 150 may be arranged end-to-end to form a row of linearly reflective elements 150 along the length of reflector 120, and two or more such rows may be arranged side-by-side to form a reflector 120. Typically, the lengths of linear reflective elements 150 are much greater than their widths. Hence, linear reflective elements 150 typically have the form of reflective slats.

In the illustrated example, linear reflective elements 150 each have a width of about 75 millimeters (mm) and a length of about 2440 mm. In other variations, linear reflective elements 150 may have, for example, widths of about 20 mm to about 400 mm and lengths of about 1000 mm to about 4000 mm. Linear reflective elements 150 may be flat or substantially flat, as illustrated, or alternatively may be curved along a direction transverse to their long axes to individually focus incident solar radiation onto the corresponding receiver. Although FIG. 1C shows light rays 370a, 370b and 370c all converging on a single point on surface 112 of receiver 110, the figures are for illustrative purposes only and should not be understood to be limiting. Typically, the reflective surfaces of linear reflective elements 150 together direct the incident solar radiation to focus generally uniformly across the flat light receiving surface 112 of receiver 110. The reflective elements 150 may have a width approximately equal to, or wider than, the corresponding light receiving surfaces 112 of the receivers. In such cases each linear reflective element 150 may reflect light so that is distributed evenly over the entire width of the light receiving surface of the receiver, which may provide a more efficient use of solar cells positioned thereon.

Although in the illustrated example each reflector 120 comprises linear reflective elements 150, in other variations a reflector 120 may be formed from a single continuous reflective element, from two reflective elements, or in any other suitable manner. Such reflectors may be arranged end-to-end along the rotation axis with adjacent ends vertically offset and optionally overlapped similarly to as described below for the illustrated examples.

Linear reflective elements 150, or other reflective elements used to form a reflector 120, may be or comprise, for example, any suitable front surface mirror or rear (back) surface mirror. The reflective properties of the mirror may result, for example, from any suitable metallic or dielectric coating or polished metal surface. In other variations, reflective elements 150 may be any suitable reflective material.

In variations in which reflectors 120 comprise linear reflective elements 150 (as illustrated), solar energy collector 100 may be scaled in size and concentrating power by adding or removing rows of linear reflective elements 150 to or from reflectors to make the reflectors wider or narrower, and the dimensions of transverse reflector supports 155 (described below) or other supporting structure adjusted accordingly. Similarly, in variations in which reflectors 120 comprise linear reflective elements arranged side-by-side on reflector trays (e.g., flexible sheets) 190 as described further below, the number of linear reflective elements on such a tray and the width of the tray may be varied, or the number of such trays arranged side-by-side transverse to the optical axis of reflectors 120 may be varied, and the dimensions of transverse reflector supports 155 or other supporting structure adjusted accordingly.

Referring again to FIGS. 1A-1C, each receiver 110 may comprise solar cells (not shown) located, for example, on receiver surface 112 to be illuminated by solar radiation concentrated by a corresponding reflector 120. In other variations, each receiver 110 may further comprise one or more coolant channels accommodating flow of liquid coolant in thermal contact with the solar cells. For example, liquid coolant (e.g., water, ethylene glycol, or a mixture of the two) may be introduced into and removed from a receiver 110 through manifolds (not shown) at either end of the receiver located, for example, on a rear surface of the receiver shaded from concentrated radiation. Coolant introduced at one end of the receiver may pass, for example, through one or more coolant channels (not shown) to the other end of the receiver from which the coolant may be withdrawn. This may allow the receiver to produce electricity more efficiently (by cooling the solar cells) and to capture heat (in the coolant). Both the electricity and the captured heat may be of commercial value.

In some variations, the receivers 110 comprise solar cells but lack channels through which a liquid coolant may be flowed. In other variations, the receivers 110 may comprise channels accommodating flow of a liquid to be heated by solar energy concentrated on the receiver, but lack solar cells. Solar energy collector 100 may comprise any suitable receiver 110. In addition to the examples illustrated herein, suitable receivers may include, for example, those disclosed in U.S. patent application Ser. No. 12/622,416, filed Nov. 19, 2009, titled “Receiver For Concentrating Photovoltaic-Thermal System;” and U.S. patent application Ser. No. 12/774,436, filed May 5, 2010, also titled “Receiver For Concentrating Photovoltaic-Thermal System;” both of which are incorporated herein by reference in their entirety.

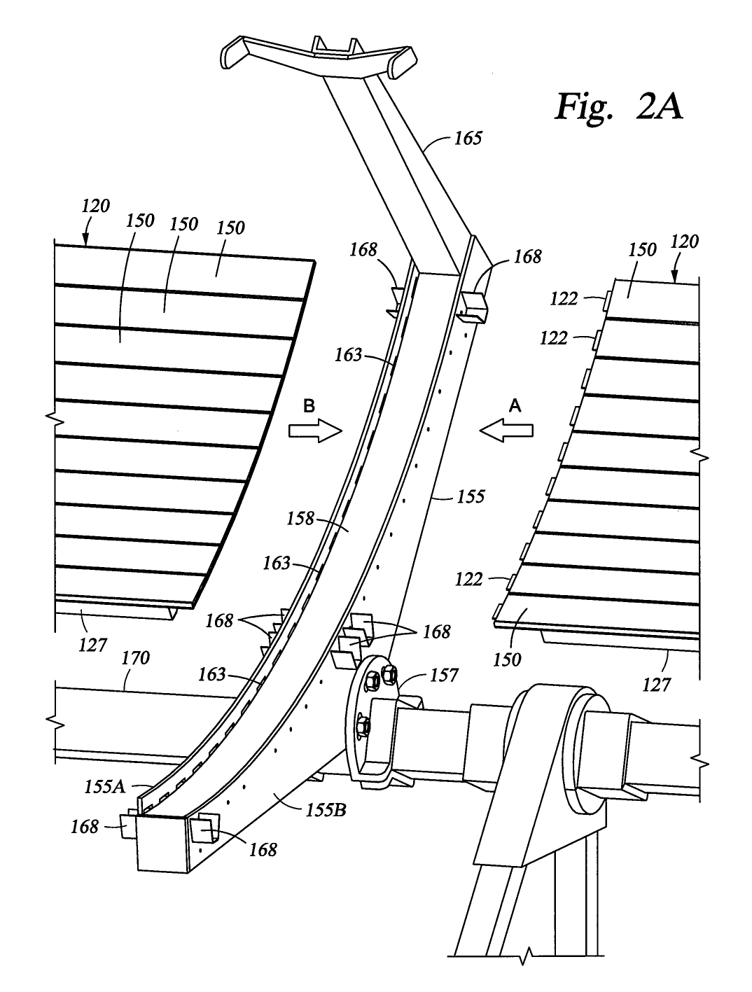

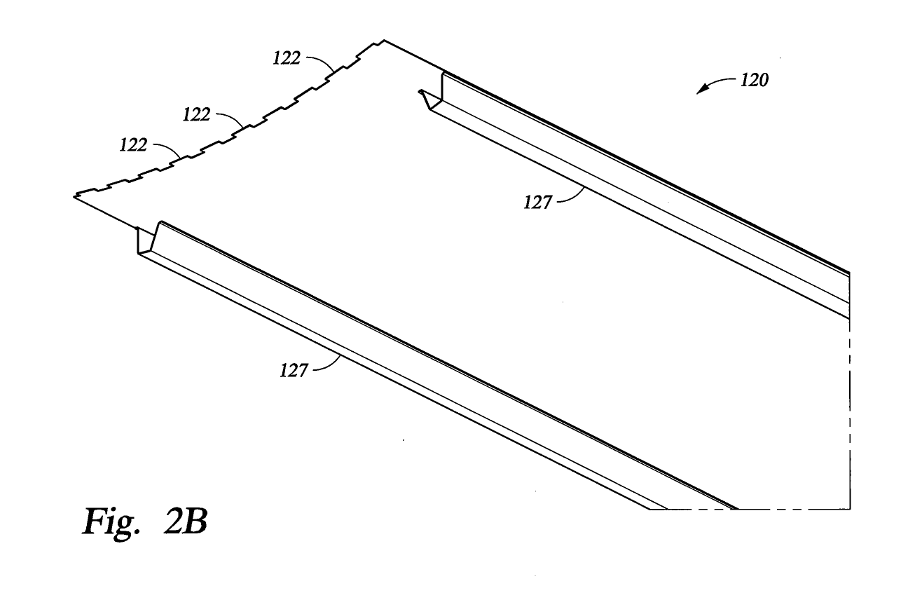

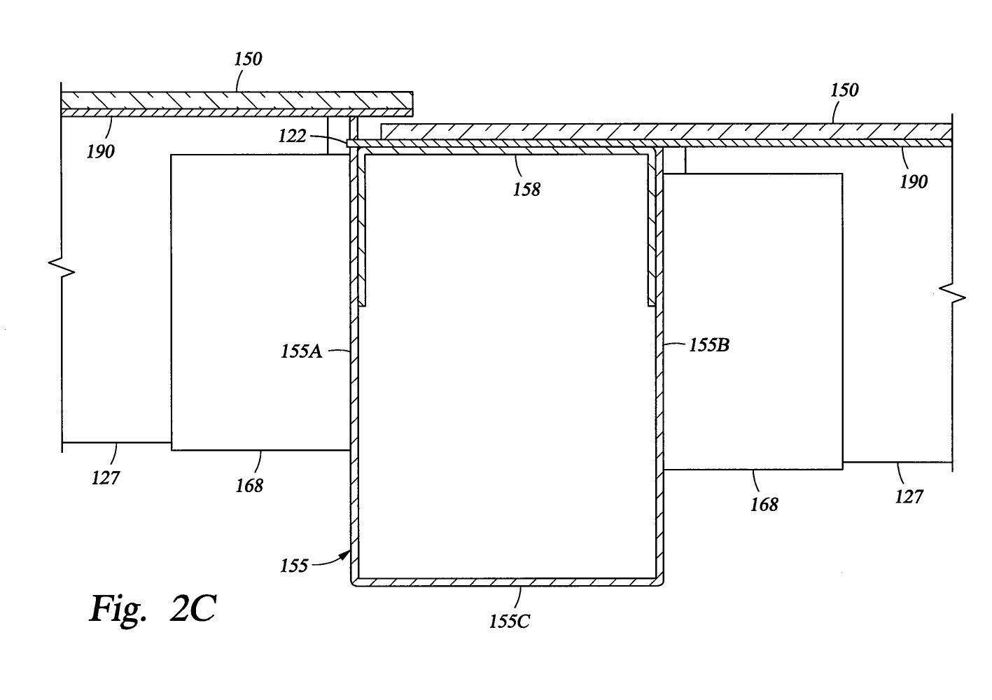

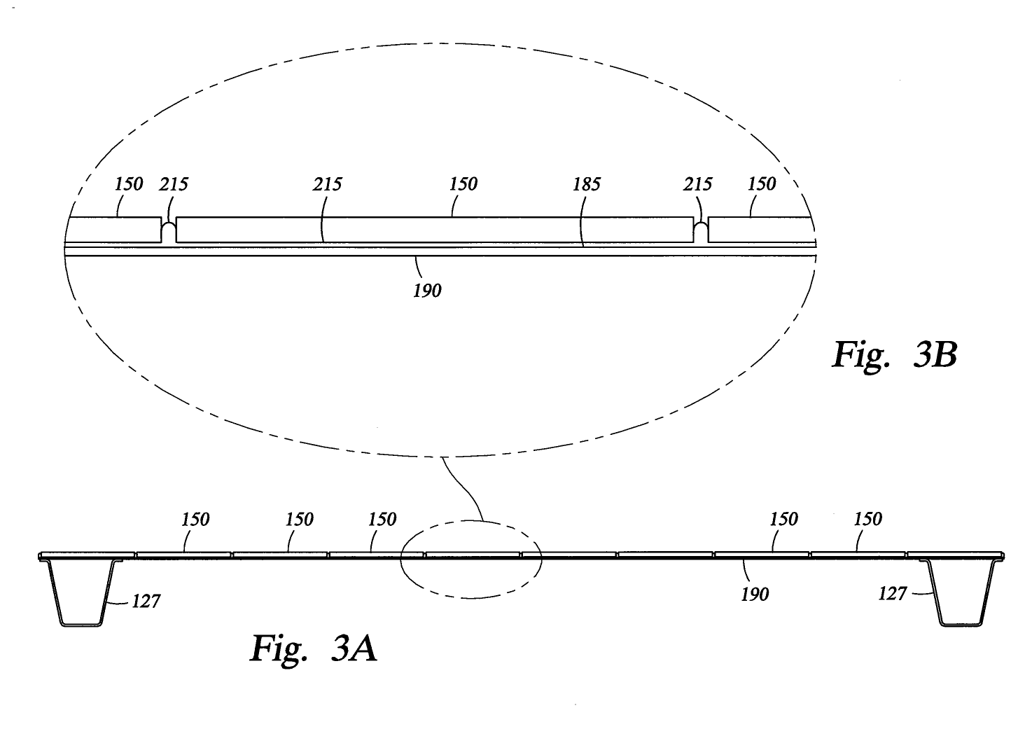

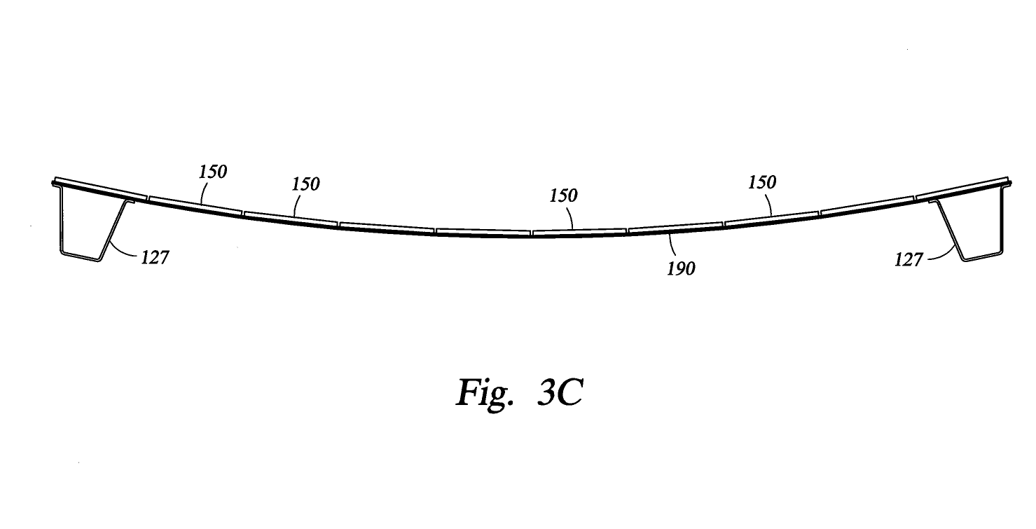

Referring again to FIGS. 1A-1C as well as to FIGS. 2A-2C and FIGS. 3A-3C, in the illustrated example each reflector 120 comprises one or more reflector trays 190, and support structure 130 comprises a plurality of transverse reflector supports 155. Each reflector tray 190 supports a plurality of linear reflective elements 150 positioned side-by-side with their long axes parallel to the rotation axis of the reflector. Each transverse reflector support 155 extends curvelinearly and transversely to the rotation axis 140 of the reflector 120 it supports. Transverse reflector supports 155 support reflector trays 190 and thus reflectors 120.

Support structure 130 also comprises a plurality of receiver supports 165 each connected to and extending from an end, or approximately an end, of a transverse reflector support 155 to support a receiver 110 over its corresponding reflector 120. As illustrated, each reflector 120 is supported by two transverse reflector supports 155, with one transverse reflector support 155 at each end of the reflector 120. Similarly, each receiver 110 is supported by two receiver supports 165, with one receiver support 165 at each end of receiver 110 (FIGS. 1A and 1B). Other configurations using different numbers of transverse reflector supports per reflector and different numbers of receiver supports per receiver may be used, as suitable. The arrangement of receiver supports 165 and transverse reflector supports 155 is configured to enable the receivers 110 to be positioned at a focal plane of the reflective surface of the reflectors 120, to where the paths of light reflected from the reflected surface are narrowed (concentrated) to a dimension near the width dimension of the light receiving surface of the receiver.

In the illustrated example, each transverse reflector support 155 for a row of reflectors 120 is attached to a rotation shaft 170 which provides for common rotation of the reflectors and receivers in that row about their rotation axis 140, which is coincident with rotation shaft 170. (The reflectors and receivers are fixed relative to each other, but their angular orientation can change to cause the reflectors to maintain an optimal position with respect to the changing position of the sun). Rotation shafts 170 may be pivotably supported by bearing posts, for example, and driven by slew drives. In other variations, any other suitable rotation mechanism may be used.

In the example shown in FIG. 2A, transverse reflector support 155 is attached to rotation shaft 170 with a two-piece clamp 157. Clamp 157 has an upper half attached (for example, bolted) to transverse reflector support 155 and conformingly fitting an upper half of rotation shaft 170. Clamp 157 has a lower half that conformingly fits a lower half of rotation shaft 170. The upper and lower halves of clamp 157 are attached (for example, bolted) to each other and tightened around rotation shaft 170 to clamp transverse reflector support 155 to rotation shaft 170. In some variations, the rotational orientation of transverse reflector support 155 may be adjusted with respect to the rotation shaft by, for example, about +/−5 degrees. This may be accomplished, for example, by attaching clamp 157 to transverse reflector support 155 with bolts that pass through slots in the upper half of clamp 157 to engage threaded holes in transverse reflector support 155, with the slots configured to allow rotational adjustment of transverse reflector support 155 prior to the bolts being fully tightened. Rotation shaft 170 is illustrated as a square shaped shaft, but in practice different shapes may be used including round or oval, or any other suitable linear support structure such as a truss.

Referring again to FIG. 1C and FIGS. 2A and 2C, in the illustrated example each of the transverse reflector supports 155 comprises sidewalls 155A and 155B, bottom wall 155C and cross bar 158. Typically, one sidewall of a single transverse reflector support 155 supports one end of a first reflector 120 and the opposing sidewall supports the adjacent end of another reflector 120 with the two reflectors 120 arranged linearly end-to-end along the rotation axis. The curved upper portions of sidewalls 155A and 155B provide reference surfaces that orient reflectors 120, and the linear reflective elements 150 that they comprise, in a desired orientation with respect to a corresponding receiver 110 with a precision of, for example, about 0.5 degrees or better (i.e., a tolerance less than about 0.5 degrees). In other variations, this tolerance may be, for example, greater than about 0.5 degrees. The upper portion of the sidewalls 155A and 155B of the transverse reflector supports 155 may have any curvature (e.g., a parabolic curvature) suitable for concentrating solar radiation reflected from the reflectors 120 mounted thereon to receiver 110.

In the illustrated example sidewall 155A is taller than sidewall 155B. This is typically the case for transverse reflector supports that are not located at an end of the solar energy collector. As best seen in FIG. 2C, as a result of this difference in height, the adjacent ends of two reflectors 120 supported by a shared transverse reflector support 155 are vertically offset with respect to each other. Potential advantages of this configuration are described further below. In the illustrated example, the vertical offset is sufficient that the end of one reflector 120 may be positioned beneath the adjacent end of the other reflector 120 in an overlapping manner. The vertical offset need not be so great as to enable such overlap, however. Further, even if the vertical offset accommodates such overlap, overlapping of the adjacent reflector ends is optional. Transverse reflector supports 155 at the extreme ends of the solar energy collector support only one reflector, and may have sidewalls having the same heights. In other variations not employing vertically offset reflector ends, all transverse reflector supports wherever positioned in the solar energy collector may have sidewalls with the same heights.

Sidewalls 155A and 155B of reflector supports 155 can include integrated features to secure the reflectors 120 to transverse reflector supports 155. For example, in the illustrated example slots 163 positioned at the upper edge of sidewall 155A are distributed from end-to-end over the transverse length of transverse reflector support 155 to enable tabs 122 at one edge of a longitudinal end of a reflector tray 190 to slide into slots 163 to secure reflector 120 in position. In the illustrated example, only side wall 155A comprises slots 163. In other variations, both sidewalls may comprise such slots. Additional features that enable transverse reflector support 155 to secure reflector 120 include joist hangers 168 positioned on the outer sidewall 155A and 155B of the transverse reflector support 155 and placed so as to capture the ends of stretcher bars 127 as shown in FIG. 2A-2C. Stretcher bars 127, positioned lengthwise along each edge of reflector 120, provide strength and stability to reflector 120 and further support reflector 120 during periods of high wind or heavy snow. The ends of stretcher bar 127 may be secured to joist hangers 168 by any mechanical means including bolts and rivets (not shown).

As illustrated by arrow A in FIG. 2A, during assembly the edge of a first reflector 120 that includes tabs 122 is placed on a sidewall 155B and slid into place in the direction of arrow A to enable the tabs 122 to slip into slots 163 in the opposite sidewall 155A thus securing the reflector 120 into position on transverse reflector support 155. The arrow B illustrates the direction a second reflector 120 is moved to be positioned on the taller sidewall 155A of the same transverse reflector support. The edge of the second reflector is secured to transverse reflector support 155 by means of the ends of stretcher bars 127 placed in and mechanically connected (not shown) to joist hangers 168 (best shown in FIGS. 2A and 2C). In the illustrated example, only one end of reflectors 120 comprise tabs 122. In some variations, clips or other connectors may be added between transverse reflector support 155 and the end of the reflector 120 that does not have tabs 122 to further secure the reflector 120 to transverse reflector support 155.

FIGS. 3A-3C show cross-sectional side views of an example reflector 120 viewed perpendicularly to its long axis. In the illustrated example, reflector 120 includes a reflector tray 190 comprising an upper tray surface 185 and stretcher bars 127 which serve as longitudinal support frames. Linear reflective elements 150 are positioned side-by-side on the upper tray surface 185 of reflector tray 190 with a small gap extending the length of reflector tray 190 between each of the linear reflective elements 150 (as shown in FIG. 1A).

In the illustrated example, reflector tray 190 is about 2440 mm long and about 600 mm wide (sized to accommodate 8 linear reflective elements). In other variations, reflector tray 190 is about 1000 mm to about 4000 mm long and about 300 mm to about 800 mm wide. Reflector tray 190 may have any suitable dimensions.

Referring to FIG. 3B, each linear reflective element 150 is held in place on the upper tray surface 185 with glue or other adhesive 215. The adhesive 215 may coat the entire upper tray surface 185 or only a portion or portions of the upper surface 185. The adhesive may coat the complete underside of the linear reflective elements 150, or only portions of the underside of reflective elements 150. A filler material such as silicon sealant or other bonding agent may optionally be used to fill gaps and provide a seal between reflective elements 150. Any other suitable method of attaching the linear reflective element 150 to the reflector tray 190 may be used, including adhesive tape, screws, bolts, rivets, clamps, springs and other similar mechanical fasteners, or any combination thereof.

In addition to attaching linear reflective elements 150 to upper tray surface 185, in the illustrated example adhesive 215 positioned between the outer edges of the rows of linear reflective elements 150 and covering the outer edges of the outermost linear reflective element 150 may also seal the edges of the linear reflective elements 150 and thereby prevent corrosion of linear reflective elements 150. This may reduce any need for a sealant separately applied to the edges of the linear reflective elements 150. Adhesive 215 positioned between the bottom of the linear reflective element 150 and upper tray surface 185 may mechanically strengthen the linear reflective element 150 and also maintain the position of linear reflective elements 150 should they crack or break. Further, reflector tray 190 together with adhesive 215 may provide sufficient protection to the rear surface of the linear reflective element 150 to reduce any need for a separate protective coating on that rear surface to protect reflective element 150 from scratching, chemicals and environmental conditions such as dust, dirt and water.

The reflector tray 190 to which the linear reflective elements 150 are adhered may be made, for example, of sheet metal or other similar material with elastic properties and a thickness that allows the reflector tray 190 to flex and bend to match the curvature of transverse reflector supports 155 to form a parabolic or similarly suited curved shape. Typically, the reflector tray 190 will bend primarily between the reflective elements 150, because the stiffness of the combination of the metal of the reflector tray 190 and the reflective elements 150 is greater than the stiffness of the metal of the reflector tray 190 alone. The flexible properties of reflector trays 190 allow them to be manufactured and shipped with a flat free-state profile and subsequently bent or flexed into their final shape in the field during the assembly of collector 100. For example, during assembly a reflector tray 190 may be positioned in its flat free-state profile above support structure 130, and then a force applied to deflect or bend the reflector tray against the transverse reflector supports 155 and conform it to their curvature. Because of the elastic properties of the reflector trays 190, when they are securely attached to the transverse reflector supports 155 they may exert a restoring force that would return them to their flat free-state profile if they were not secured in their curved configuration. This restoring force may provide structural strength to reflector 120. In addition, the flexible nature of the reflector tray 190 materials may help prevent warping of reflector 120 (and breaking of linear reflective elements 150) if materials with a different coefficient of thermal expansion are used for transverse reflector support 155 than the materials used for reflector tray 190.

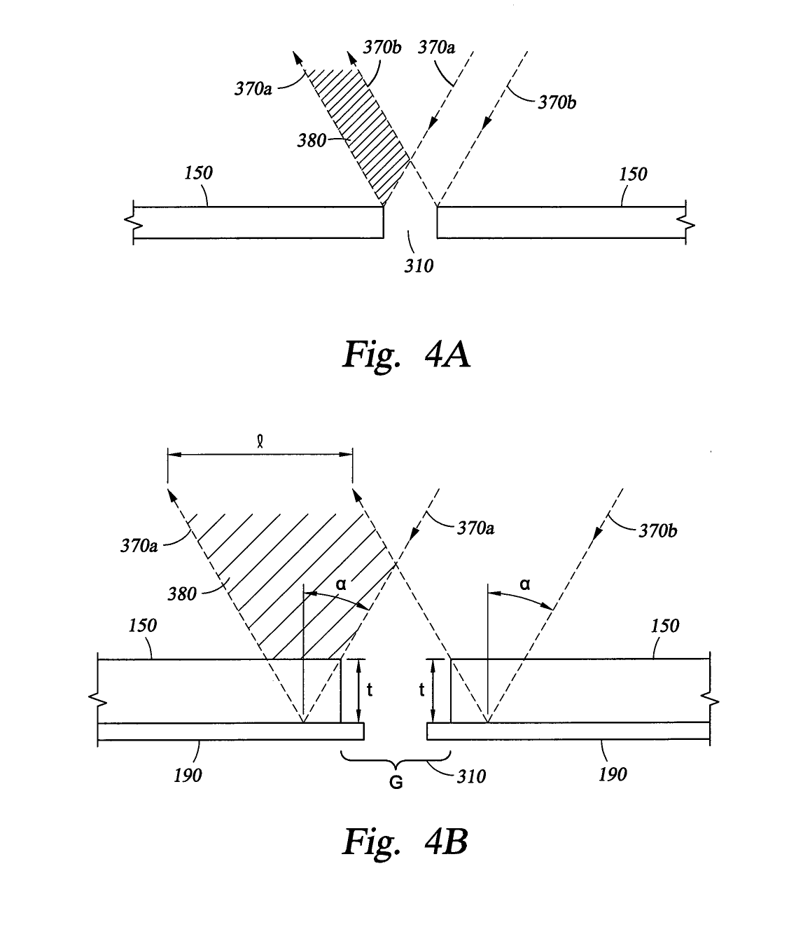

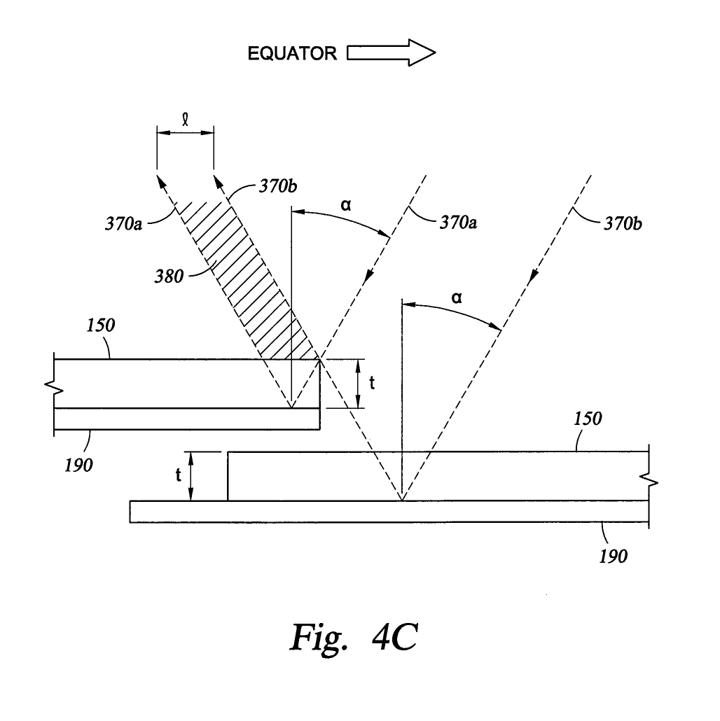

Referring again to FIG. 1A, reflectors 120 are arranged linearly end-to-end along the length of the collector 100. Gaps between adjacent ends of reflectors in the solar energy collector 100, if present, may cause shadows that produce non-uniform illumination of the receiver that degrades performance of solar cells on the receiver. As shown in FIG. 4A, for example, light rays 370a, 370b incident on adjacent ends of front surface linear reflective elements 150 on opposite sides of a gap 310 are reflected in parallel and hence cast a shadow 380 because no light is reflected from the gap 310. If back surface reflective elements are used instead, as shown in FIG. 4B, shadow 380 is even wider. In such embodiments the light rays 370a and 370b go through a transparent layer of the reflective element to the reflective surface below and are reflected back through the transparent layer. Incident or reflected light rays that intersect the edges of the transparent layers adjacent to gap 310 are scattered rather than directed to the receiver. The shadow 380 resulting from the combination of the gap 310 with such scattering has a length of l=2t(tan α)+G, where “t” is the thickness of the glass, “α” is the angle of incidence of the light rays 370a and 370b on the reflectors, and “G” is the width of the gap between adjacent ends of the reflectors. The length “l” of shadow 380 will never be less than the size of the gap “G”.

Referring now to FIGS. 2A, 2C, and 4C, the width of shadow 380 may be significantly reduced by arranging the ends of adjacent reflectors 120 (e.g., the ends of adjacent reflector trays 190) to be vertically offset and optionally overlapped as described above. Typically, the upper reflector is positioned further from the equator than is the lower reflector. Referring particularly to FIG. 4C, in such a vertically offset geometry a light ray 370b reflected from the lower reflector may pass arbitrarily close to the corner of the upper reflector. This effectively eliminates gap G for the illustrated angle of incidence. The figures show the vertically offset reflectors in an overlapping configuration. Such overlap is optional, but may be advantageous for low angles of incidence α. The amount of vertical offset and optional overlap may be selected to effectively eliminate gap G for all angles of incidence a expected during operation of the solar energy collector. In such embodiments, shadow 380 has a width of l=2t(tan α), which may be very small. In contrast, if the upper reflector were closer to the equator than the lower reflector, shadow 380 would have a length that was disadvantageously increased by the vertical offset of the reflector ends.

This disclosure is illustrative and not limiting. Further modifications will be apparent to one skilled in the art in light of this disclosure and are intended to fall within the scope of the appended claims. All publications and patent application cited in the specification are incorporated herein by reference in their entirety.

1. A solar energy collector comprising:
a linearly extending receiver comprising solar cells;
at least a first, a second, and a third trough reflector arranged end-to-end with their linear foci oriented parallel to a long axis of the receiver and located at or approximately at the receiver, the trough reflectors fixed in position with respect to each other and with respect to the receiver; and
a linearly extending support structure that accommodates rotation of the trough reflectors and the receiver about a rotation axis parallel to the long axis of the receiver;
wherein the second trough reflector is positioned between the first and third trough reflectors with a first end of the second trough reflector adjacent to an end of the first trough reflector and a second end of the second trough reflector adjacent to an end of the third trough reflector, the first end of the second trough reflector is vertically offset from the end of the first trough reflector with the end of the first trough reflector closer to the receiver than is the first end of the second trough reflector, and the second end of the second trough reflector is vertically offset from the end of the third trough reflector with the second end of the second trough reflector closer to the receiver than is the end of the third trough reflector.

2. The solar energy collector of claim 1, installed at a site for operation with the first trough reflector further from the equator than is the third trough reflector.

3. The solar energy collector of claim 1, wherein the end of the first trough reflector and the first end of the second trough reflector overlap, and the second end of the second trough reflector and the end of the third trough reflector overlap.

4. The solar energy collector of claim 3, installed at a site for operation with the first trough reflector further from the equator than is the third trough reflector.

5. The solar energy collector of claim 1, wherein each trough reflector comprises a plurality of reflective slats oriented with their long axes parallel to the long axis of the receiver and arranged side-by-side in a direction transverse to the long axis of the receiver on a flexible sheet of material to which they are attached.

6. The solar energy collector of claim 5, wherein the reflective slats are attached to the flexible sheets with an adhesive that covers the entire bottom surface of each reflective slat.

7. The solar energy collector of claim 5, wherein the reflective slats are attached to the flexible sheets with an adhesive that seals the edges and bottom surfaces of the reflective slats.

8. The solar energy collector of claim 5, wherein the reflective slats are flat or substantially flat.

9. The solar energy collector of claim 5, wherein the flexible sheet is a flexible metal sheet.

10. The solar energy collector of claim 5, wherein each flexible sheet is flexed to match a curvature of an underlying portion of the support structure to which it is attached, thereby orienting its reflective slats to concentrate solar radiation onto the receiver during operation of the solar energy collector.

11. The solar energy collector of claim 10, comprising a plurality of transverse reflector supports extending away from the rotation axis and providing the curvature to which the flexible sheets are matched.

12. The solar energy collector of claim 10, wherein the flexible sheet with attached reflective slats has a flat free state when not secured to the support structure and exerts a restoring force to return to the flat free state when flexed to match the curvature of the underlying portion of the support structure.

13. (canceled)

14. The solar energy collector of claim 5, wherein the end of the first trough reflector and the first end of the second trough reflector overlap, and the second end of the second trough reflector and the end of the third trough reflector overlap.

15. The solar energy collector of claim 5, installed at a site for operation with the first trough reflector further from the equator than is the third trough reflector.

16. The solar energy collector of claim 5, wherein the end of the first trough reflector and the first end of the second trough reflector are attached to and supported by a first shared transverse reflector support extending away from the rotation axis of the collector, and the second end of the second trough reflector and the end of the third trough reflector are attached to and supported by a second shared transverse reflector support extending away from the rotation axis of the reflector.

17-18. (canceled)

19. The solar energy collector of claim 14, installed at a site for operation with the first trough reflector further from the equator than is the third trough reflector.

20. (canceled)
